(19) United States
(12) Patent Application Publication
(10) Pub. No.: US 2004/0072446 A1
(43) Pub. Date: Apr. 15, 2004

(54) Method for fabricating an ultra shallow junction of a field effect transistor

(75) Inventors: Wei Liu, San Jose, CA (US); David S. L. Mui, Fremont, CA (US); Lance A. Scudder, Santa Clara, CA (US); Paul B. Comita, Menlo Park, CA (US); Arkadii V. Samoilov, Sunnyvale, CA (US); Babak Adibi, Los Altos, CA (US)

Correspondence Address: Applied Materials, Inc., Patent Counsel, P.O. Box 450A, Santa Clara, CA, 95052, US

(73) Assignee: Applied Materials, Inc.

(21) Appl. No.: 10/612,642

(22) Filed: Jul. 1, 2003

Related U.S. Application Data
(60) Provisional application No. 60/393,393, filed on Jul. 2, 2002.

(51) Int. Cl. H01L 21/336; H01L 21/302; H01L 21/461

(52) U.S. Cl. 438/719; 438/300; 438/756

(57) ABSTRACT

A method of fabricating an ultra shallow junction of a field effect transistor is provided. The method includes the steps of etching a substrate near a gate structure to define a source region and a drain region of the transistor, forming a spacer/protective film having poor step coverage to protect frontal surfaces of the source and drain regions, laterally etching sidewalls of the regions beneath a gate dielectric to define a channel region, and removing the protective film.

### CROSS-REFERENCE TO RELATED APPLICATIONS

This application claims benefit of U.S. provisional patent application serial No. 60/393,393, filed Jul. 2, 2002, which is herein incorporated by reference.

### BACKGROUND OF THE INVENTION

1. Field of the Invention

The present invention generally relates to a method for fabricating devices on semiconductor substrates. More specifically, the present invention relates to a method for fabricating a field effect transistor.

2. Description of the Related Art

Ultra-large-scale integrated (ULSI) circuits typically include more than one million transistors that are formed on a semiconductor substrate and which cooperate to perform various functions within an electronic device. Such transistors may include complementary metal-oxide-semiconductor (CMOS) field effect transistors.

A CMOS transistor includes a gate structure that is disposed between a source region and a drain region defined in the semiconductor substrate. The gate structure generally comprises a gate electrode formed on a gate dielectric material. The gate electrode controls a flow of charge carriers, beneath the gate dielectric, in a channel region that is formed between the drain region and the source region, so as to turn the transistor on or off. The channel, drain, and source regions are collectively referred to in the art as a “transistor junction”. There is a constant trend to reduce dimensions of the transistor junction and, in particular, decrease the channel region width in order to facilitate an increase in the operational speed of such transistors.

The gate electrode is generally formed of doped polysilicon (Si) while the gate dielectric material may comprise a thin layer (e.g., <20 Angstoms) of a high dielectric constant material (e.g., a dielectric constant greater than 4.0) such as silicon dioxide (SiO₂) or N-doped silicon dioxide, and the like.

The CMOS transistor may be fabricated by defining source and drain regions in the semiconductor substrate using an ion implantation process. However, smaller dimensions for the transistor junctions has necessitated the formation of source and drain regions with reduced depths (e.g., depths of between 100 to 500 Angstroms). Such ultra shallow junctions require abrupt interfaces that are difficult to form using ion implantation techniques due to ion-channeling and transient diffusion phenomena.

Another method for fabricating the ultra shallow transistor junctions comprises forming a gate structure on a silicon substrate, etching ultra shallow trenches in the substrate close to the gate structure, and then forming the source and drain regions of the transistor in such trenches using a suitable vacuum deposition technique. However, for this method, the length of the channel region in the transistor junction cannot be made smaller than a width of the gate structure.

Therefore, there is a need in the art for an improved method for fabricating an ultra shallow junction of a field effect transistor.

### SUMMARY OF THE INVENTION

The present invention is a method for fabricating an ultra shallow junction of a field effect transistor on a semiconductor substrate (e.g., a silicon (Si) wafer). The transistor is formed by etching the substrate near a gate structure to define a source region and a drain region, forming a spacer/protective film having poor step coverage to protect frontal surfaces of the source and drain regions, laterally etching the substrate beneath a gate dielectric layer to define a channel region of the transistor, and removing the spacer/protective film.

In one embodiment, the spacer/protective film is formed using a directional plasma oxidation process. In other embodiments, the spacer/protective film may comprise an oxide layer, a nitride layer or an amorphous carbon layer that is resistant to the etch chemistry employed to create an undercut profile beneath the gate dielectric layer.

### BRIEF DESCRIPTION OF THE DRAWINGS

The teachings of the present invention can be readily understood by considering the following detailed description in conjunction with the accompanying drawings, in which:

FIGS. 1A-1C depict flow diagrams of exemplary embodiments for a method of fabricating an ultra shallow junction of a field effect transistor in accordance with the present invention;

FIGS. 2A-2M depict a series of schematic, cross-sectional views of a substrate having an ultra shallow junction being formed in accordance with the embodiments of FIGS. 1A-1C;

FIG. 3 depicts a schematic diagram of an exemplary microwave plasma apparatus of the kind used in performing portions of the inventive method; and

FIG. 4 depicts a schematic diagram of an exemplary plasma etch apparatus of the kind used in performing portions of the inventive method.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method of fabricating an ultra shallow junction of a field effect transistor, e.g., a CMOS transistor. The transistor is formed by etching a substrate surface (e.g., silicon (Si) wafer) near a gate structure to define a source region and a drain region, forming a spacer/protective film having poor step coverage to protect frontal surfaces of the source and drain regions, laterally etching the substrate beneath a gate dielectric layer to define a channel region of the transistor, and removing the spacer/protective film as well as post-etch residue.

In one embodiment, the frontal surfaces of the source and drain regions are oxidized using a directional plasma oxidation process that forms a spacer/protective film of silicon dioxide (SiO₂) on the frontal surfaces, while leaving the sidewalls of the source and drain regions unprotected for subsequent lateral etching.

In other embodiments, the spacer/protective film may comprise an oxide layer, a nitride layer or an amorphous carbon layer that is resistant to the etch chemistry employed to create an undercut profile beneath the gate dielectric layer.

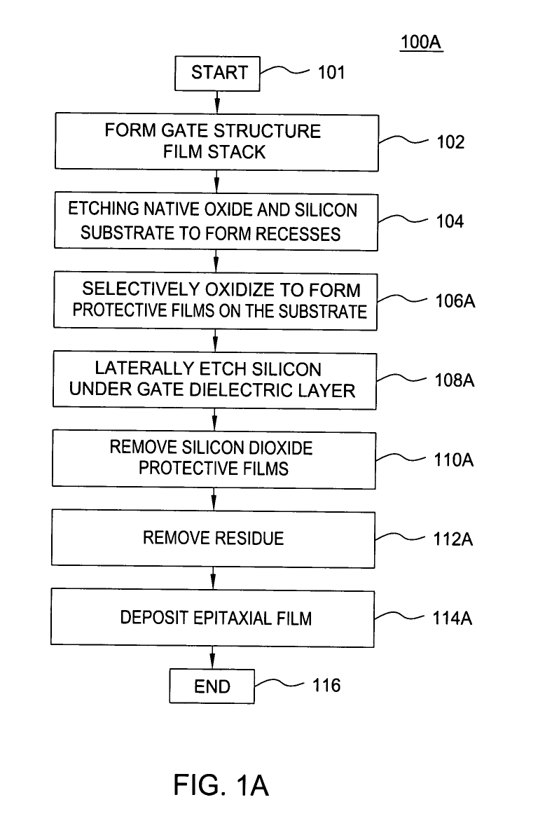

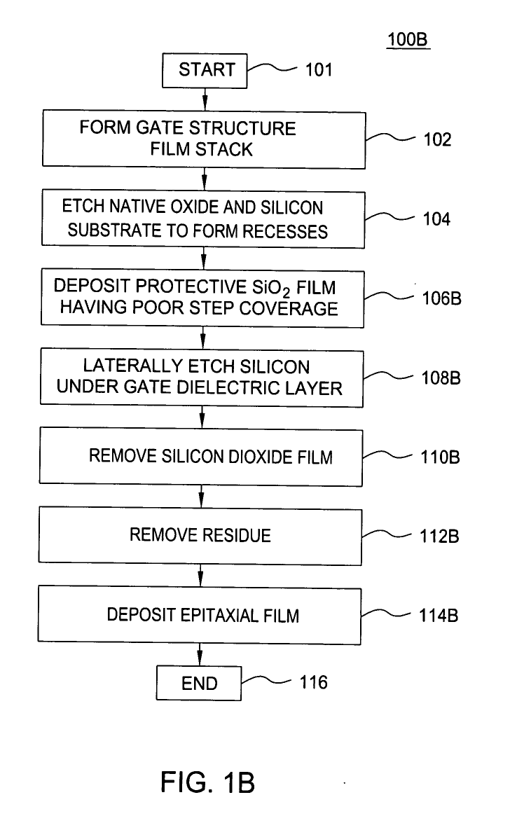

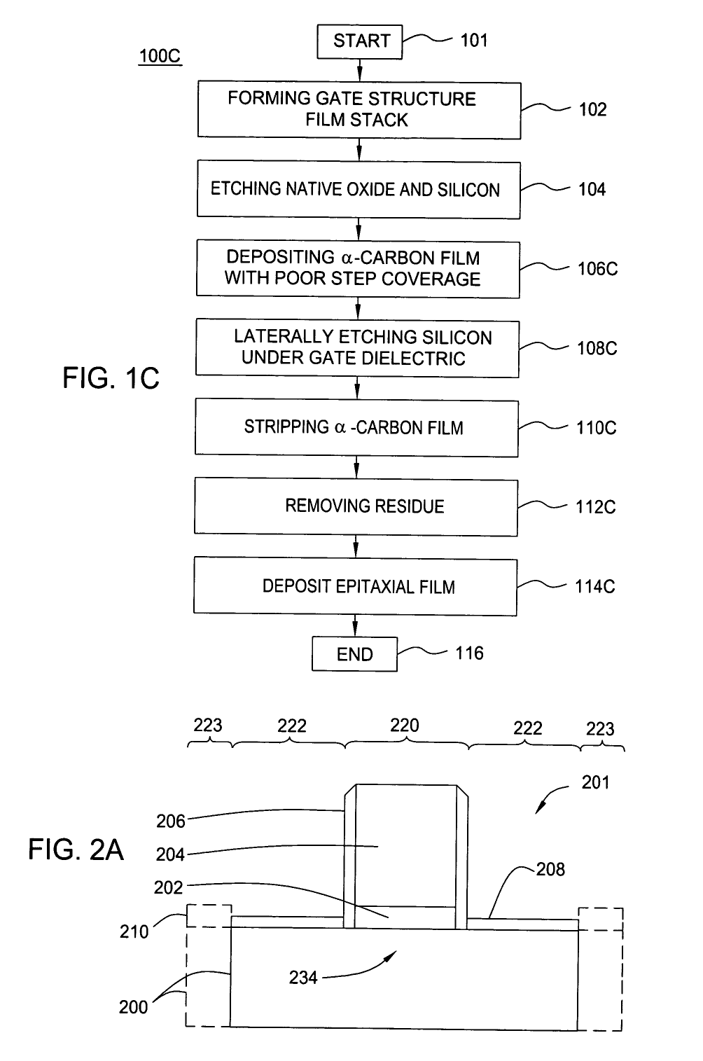

FIGS. 1A-1C depict flow diagrams of embodiments of a method for fabricating an ultra shallow junction of a field effect transistor (e.g., CMOS transistor) as sequences 100A-100C. The sequences 100A-100C include the processes for fabrication of the shallow junction that are performed upon a surface of the substrate near a gate structure of the transistor.

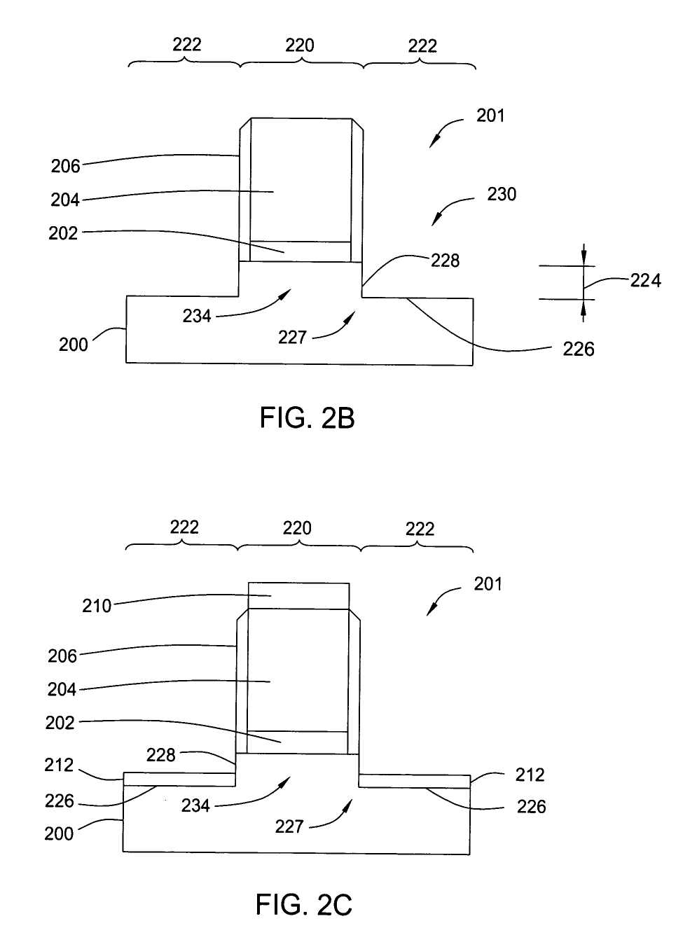

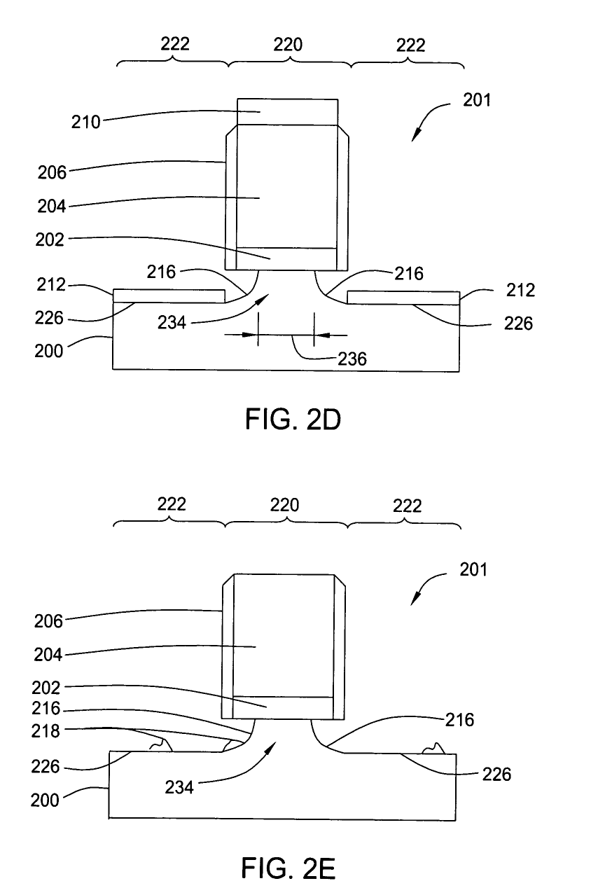

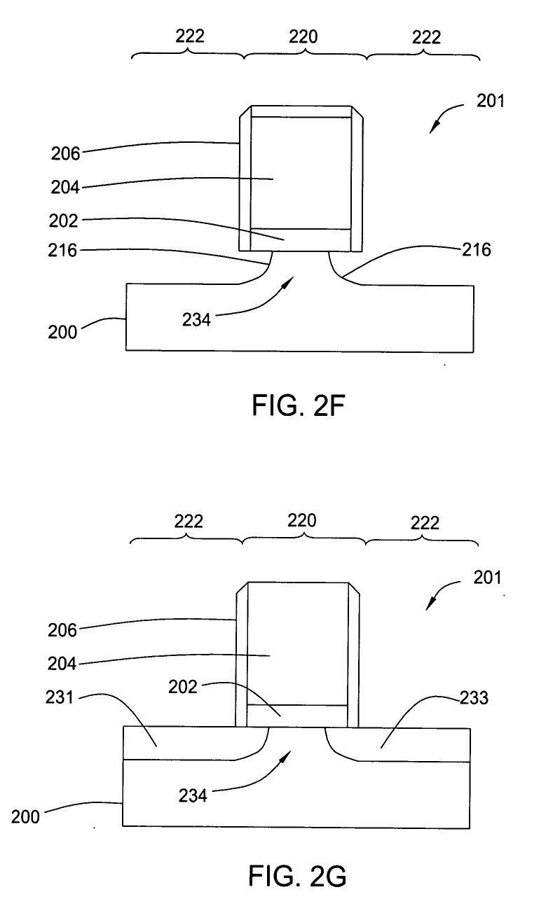

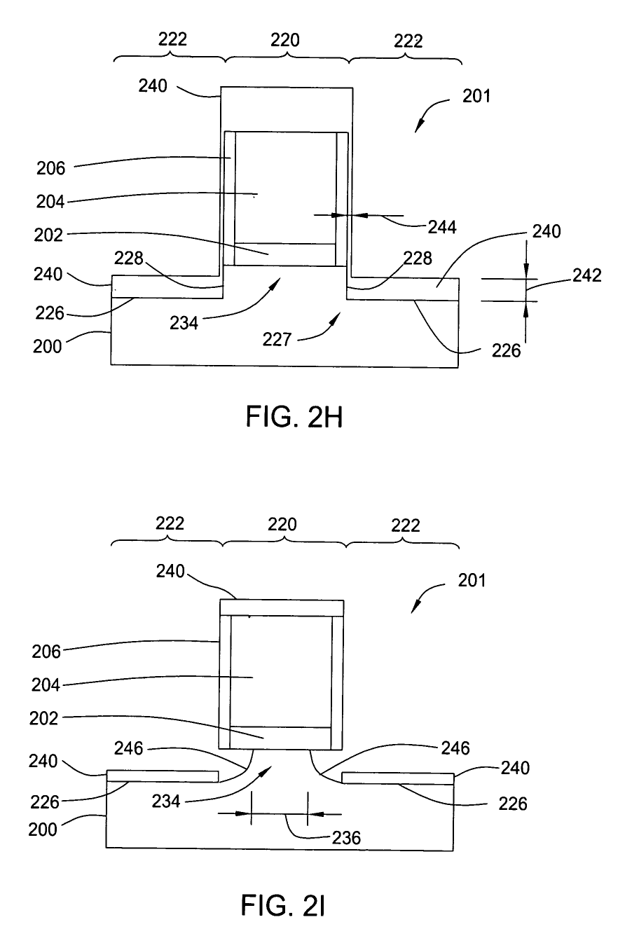

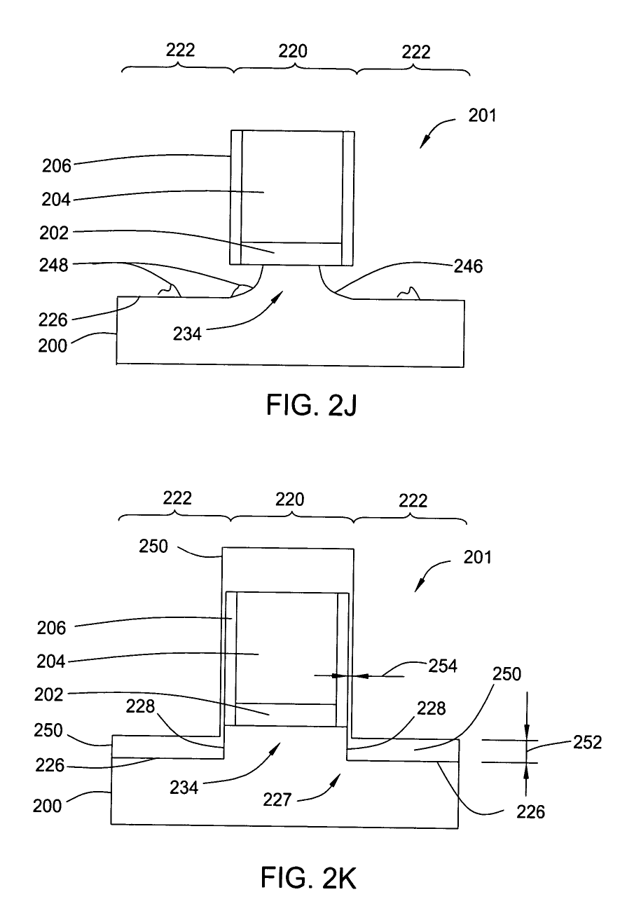

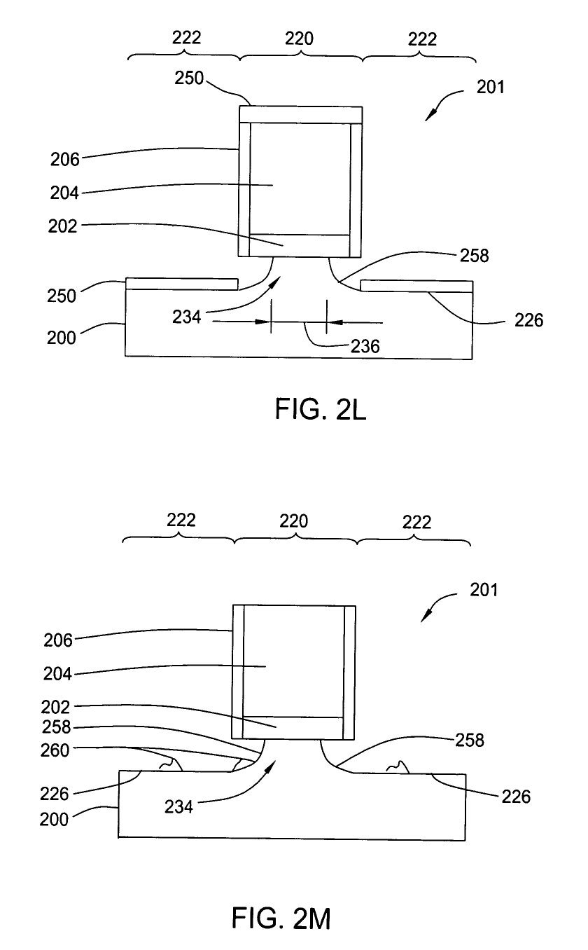

FIGS. 2A-2M depict a series of schematic, cross-sectional views of a substrate having an ultra shallow junction being formed using the sequences 100A-100C. The cross-sectional views in FIGS. 2A-2M relate to the individual processing steps used to form the ultra shallow junction. For best understanding of the invention, the reader should refer simultaneously to FIGS. 1A-1C and FIGS. 2A-2M.

The images in FIGS. 2A-2M are not depicted to scale and are simplified for illustrative purposes. Specifically, regions on the substrate that are adjacent to the ultra shallow junctions (regions 223) are depicted in FIGS. 2A and 2G only (in phantom) for purposes of graphical clarity.

The embodiment 100A starts at step 101 and proceeds to step 102.

At step 102, a gate film stack 201 of a field effect transistor is formed on a substrate 200 (e.g., a silicon (Si) wafer) (FIG. 2A). The film stack 201 generally comprises a gate dielectric layer 202, a gate electrode 204 and a spacer film 206. The substrate 200 may also have a film 208 of native silicon dioxide thereon to a thickness of between 20 to 50 Angstroms. The film stack 201 is formed in a region 220 above a channel region 234 and portions of the source region 231 and the drain region 233 (regions 222) of the ultra shallow junction being fabricated (discussed in reference to FIG. 2G). Further, regions 223 of the substrate 200 that are adjacent to the ultra shallow junction are depicted in phantom in FIG. 2A.

The gate dielectric layer 202 may comprise at least one film of a high dielectric constant material such as silicon dioxide (SiO₂), n-doped silicon dioxide, and the like. In one embodiment, the gate dielectric layer 202 is illustratively formed of silicon dioxide to a thickness of about 10 to 60 Angstroms. Generally, the gate electrode layer 204 may comprise either doped polysilicon (Si) or undoped polysilicon, while the spacer film 206 may be formed of silicon dioxide, silicon nitride (Si₃N₄), and the like.

The gate dielectric layer 202, gate electrode layer 204 and spacer film 206 may be formed using any conventional deposition technique, such as atomic layer deposition (ALD), physical vapor deposition (PVD), chemical vapor deposition (CVD) plasma enhanced CVD (PECVD), and the like. Fabrication of the CMOS field effect transistors may be performed using the respective processing modules of the CENTURA®, ENDURA®, and other semiconductor wafer processing systems available from Applied Materials, Inc. of Santa Clara, Calif.

At step 104, the substrate 200 is etched in regions 222 (i.e., source and drain regions) (FIG. 2B). Step 104 uses two etch processes, the first etch process removes the native oxide film 208 and the second etch process etches the ultra shallow junction in the substrate 200.

Step 104 can be performed in a etch reactor such as a Decoupled Plasma Source (DPS) reactor of the CENTURA® system, commercially available from Applied Materials, Inc. of Santa Clara, Calif. The DPS reactor uses a power source (i.e., an inductively coupled antenna) to produce a high-density inductively coupled plasma. To determine the endpoint of the etch process, the DPS reactor may also include an endpoint detection system that monitors plasma emissions at a particular wavelength, controls the process time, or performs laser interferometry, and the like.

In one embodiment, the native oxide film 208 may be removed using a fluorocarbon gas mixture. For one exemplary embodiment, the native oxide film 208 is removed in the DPS reactor by providing carbon tetrafluoride (CF₄) at a flow rate of 50 sccm, applying 500 W of power to the inductively coupled antenna, applying 40 W of bias power to the cathode and maintaining a wafer temperature of 50 degrees at a chamber pressure of 4 mtorr. Such an etch process provides etch selectivity for native oxide (film 208) over silicon (layer 204 and substrate 200) of 1:1.

Once the native oxide film 208 is removed, recesses 230 are defined in the substrate 200 where source regions and drain regions of the transistor are to be formed. Each recess 230 has a depth 224 of about 100 to 500 Angstroms and includes a frontal surface 226, a sidewall 228, and a corner region 227 that is adjacent to the gate film stack 201. During this step, the polysilicon gate electrode 204 is etched the same depth as the recesses, unless a sacrificial layer (not shown) was formed thereon to protect the gate film stack 201. In one illustrative embodiment, the recesses 230 are defined in the substrate 200 using a plasma etch process that includes a gas mixture comprising one or more halogen-containing gases such as chlorine (Cl₂), boron trichloride (BCl₃), carbon tetrachloride (CCl₄), hydrogen chloride (HCl), hydrogen bromide (HBr), carbon tetrafluoride (CF₄), sulfur hexafluoride (SF₆), trifluoromethane (CHF₃), difluoromethane (CH₂F₂), and the like.

In one illustrative embodiment, recesses 230 may be formed in the substrate 200 using the DPS reactor by providing hydrogen bromide (HBr) at a flow rate of 20 to 300 sccm, chlorine (Cl₂) at a flow rate of 2 to 300 sccm (i.e., a HBr:Cl₂ flow ratio ranging from 1:15 to 15:1), as well as 30% by volume of oxygen (O₂) in helium (He) at a flow rate of 0 to 200 sccm, applying power to an inductively coupled antenna between 200 and 3000 W, applying a cathode bias power between 0 and 300 W and maintaining a wafer temperature between 20 and 80 degrees Celsius at a pressure in the process chamber between 2 and 100 mtorr. One exemplary process provides hydrogen bromide (HBr) at a flow rate of 100 sccm, chlorine (Cl₂) at a flow rate of 10 sccm (i.e., a HBr:Cl₂ flow ratio of 10:1), 30% by volume of oxygen (O₂) in helium (He) at a flow rate of 12 sccm, applies 350 W of power to the inductively coupled antenna, applies 40 W of cathode bias power and maintains a wafer temperature of 45 degrees Celsius at a chamber pressure of 25 mTorr. Such a process provides etch selectivity for silicon (substrate 200) over silicon dioxide (SiO₂) of about 20:1.

At step 106A, the frontal surfaces 226 of the recesses 230 are selectively oxidized using a directional oxidation process to form a protective film 212 (FIG. 2C). In one illustrative embodiment, the directional oxidation process uses a gas comprising an oxygen (O₂) plasma that is energized using a substrate bias power source such as, e.g., radio-frequency (RF) power, to oxidize the frontal surfaces 226. In a further embodiment, the plasma may be energized using the same or another source of power (e.g., an inductively coupled plasma, capacitively coupled plasma, microwave plasma, and the like) elsewhere in the reaction volume of the process chamber. In general terms, the directional oxidation process uses ionic bombardment of the frontal surface 228 to oxidize such surface and form the protective film 212 of silicon dioxide (SiO₂) on the silicon substrate 200. The protective film 212 generally has a thickness of about 20 to 30 Angstroms, however, on other embodiments, the protective film 212 may have a different thickness.

The sidewall 228 of the recesses 230 is not oxidized during the directional oxidation process (step 106A). However, during step 106A, a protective film 210 of silicon dioxide (SiO₂) is also formed on the polysilicon gate electrode 204 having the same thickness as the protective film 212.

In one illustrative embodiment, the protective film 212 is formed on frontal surfaces 228 in the DPS reactor by providing oxygen (O₂) at a flow rate of 20 to 200, applying power to an inductively coupled antenna between 200 to 1500 W, applying a cathode bias power between 20 to 200 W and maintaining a wafer temperature between 20 and 80 degrees Celsius at a pressure in the process chamber between 3 to 20 mTorr. One exemplary process provides oxygen (O₂) at a flow rate of 100 sccm, applies 600 W of power to the inductively coupled antenna, applies 100 W of cathode bias power and maintains a wafer temperature of 50 degrees Celsius at a chamber pressure of 10 mTorr.

At step 108A, sidewalls 228 of the recesses 230 are etched using a lateral etch process (FIG. 2D). The lateral etch process removes dielectric material (e.g. silicon) beneath the gate dielectric layer 202 in the corner region 227 transforming a sidewall 228 into a surface 216 and defining a width 236 for the channel region 234 of the field effect transistor being fabricated. During step 108A, the protective film 210 protects the film stack 201, while the protective film 212 protects the source and drain regions 222. The lateral etch process continues until the channel region 234 is etched to a pre-determined width 236.

In one embodiment, step 108A uses a gas mixture comprising at least one of hydrogen bromide (HBr), carbon tetrafluoride (CF₄), chlorine (Cl₂), and the like. Such etch process is disclosed in commonly assigned U.S. patent application Ser. No. 10/194,609, filed Jul. 12, 2002 (Attorney docket number 7365), which is incorporated herein by reference.

In one illustrative embodiment, the sidewalls 228 are laterally etched using the DPS reactor by providing hydrogen bromide (HBr) at a flow rate of 20 to 300 sccm, chlorine (Cl₂) at a flow rate of 20 to 300 sccm (i.e., a HBr:Cl₂ flow ratio ranging from 1:15 to 15:1), as well as 30% by volume of oxygen (O₂) in helium (He) at a flow rate of 0 to 200 sccm, applying power to an inductively coupled antenna between 200 and 3000 W, applying a cathode bias power between 0 and 500 W and maintaining a wafer temperature between 0 and 200 degrees Celsius at a pressure in the process chamber between 2 and 100 mTorr. One exemplary process provides hydrogen bromide (HBr) at a flow rate of 120 sccm, chlorine (Cl₂) at a flow rate of 40 sccm (i.e., a HBr:Cl₂ flow ratio of 3:1), 30% by volume of oxygen (O₂) in helium (He) at a flow rate of 6 sccm, applies 700 W of power to the inductively coupled antenna, applies 65 W of cathode bias power and maintains a wafer temperature of 50 degrees Celsius at a chamber pressure of 70 mTorr. Such a process provides selectivity to silicon over the plasma oxidized silicon (i.e., silicon dioxide (SiO₂) of about 50:1. As such, during step 108A both of the silicon dioxide protective films 210, 212 are not consumed.

At step 110A, the silicon dioxide protective films 210, 212 are removed from the substrate 200 (FIG. 2E). In one illustrative embodiment, step 110A uses the process described above with reference to step 104 for removing protective films 210, 212. In one exemplary embodiment, the protective films 210, 212 are removed in the DPS reactor by providing carbon tetrafluoride (CF₄) at a flow rate of 50 sccm, applying 500 W of power to the inductively coupled antenna, applying 40 W of bias power to the cathode and maintaining a wafer temperature of 50 degrees at a chamber pressure of 4 mtorr. Such an etch process provides etch selectivity for silicon dioxide (SiO₂) (films 210, 212) over silicon (substrate 200) of 1:1.

During step 110A post-etch residues 218 may be formed on the substrate (FIG. 2E). Such post-etch residue 218 may be are removed by dipping the substrate 200 in an aqueous solution including hydrogen fluoride (HF) (FIG. 2F). In one illustrative embodiment, the aqueous solution comprises hydrogen fluoride and deionized water in a ratio of 1:100 (HF:H₂O). The hydrogen fluoride solution may additionally include between 0.5 and 15% by volume of at least one of nitric acid (HNO₃) and hydrogen chloride (HCl). After the substrate is dipped in the aqueous solution of hydrogen fluoride, the substrate is conventionally rinsed with deionized water to remove any traces of hydrogen fluoride. During immersion, the aqueous hydrogen fluoride solution may be maintained at a temperature of about 10 to 30 degrees Celsius. The duration of the wet dip process is generally between 1 and 10 minutes. One specific process uses an aqueous solution that comprises about 1% by volume of hydrogen fluoride, at a temperature of about 20 degrees Celsius (i.e., room temperature), for a duration of about 5 minutes.

At step 114, an epitaxial deposition process may be used to fill the recesses 230 forming source regions (well) 231 and drain regions (wells) 233 of the ultra shallow junction (FIG. 2G). Generally, the epitaxial deposition process is a chemical vapor deposition (CVD) process that uses at least one silicon-comprising precursor, e.g., silane (SiH₄), silicon tetrachloride (SiCl₄), trichlorosilane (SiHCl₃), dichlorosilane (SiH₂Cl₂), and the like, as well as a dopant gas such as, e.g., diborane (B₂H₆), phosphine (PH₃), arsine (AsH₃), and the like. In some cases, germanium-containing (Ge) or carbon-containing (C) dopant gases may also be included.

At step 116, the embodiment 100A ends.

The embodiment 100B (FIG. 1B), similar to the embodiment 100A, starts at step 101 and sequentially performs steps 102 and 104.

At step 106B, a film 240 of silicon dioxide is deposited on the wafer 200 (FIG. 2H). The silicon dioxide film 240 is deposited using a conventional CVD process that forms a film on the substrate having poor step coverage, e.g., about 20% or less. Herein the term “step coverage” is defined as a ratio of a thickness of a film on a sidewall to the thickness of the film on a frontal (or horizontal) surface. As such, a thickness 242 of the silicon dioxide film 240 on the frontal surface 226 is about 4-5 times greater than a thickness 244 of the film on the sidewall 228 and in the corner 227. In one illustrative embodiment, the film 240 is deposited to the thickness 242 of about 50 Angstroms, however, in other embodiments, the film 240 may be formed with a different thickness.

At step 108B, the sidewalls 228 of the recesses 230 are etched using the lateral etch process (FIG. 21). In one embodiment, steps 108B and 108A use the same etching chemistry. During a first phase, step 108B isotropically etches the film 240 and promptly exposes the sidewall 228 and corner region 227 by removing the thin film of silicon dioxide (i.e., film having the thickness 244) from the frontal surface 228 and corner region 227. During a second phase, the exposed sidewall 228 is laterally etched transforming the sidewall into a surface 246 and defining the width 236 of the channel region 234 of the field effect transistor being fabricated. Similar to step 108A, step 108B continues until the channel region 234 is etched the pre-determined width 236. In one illustrative embodiment, step 108B uses the process described above in reference to step 108A. Such process provides selectivity to silicon over CVD deposited silicon dioxide of about 10:1 and at the end of step 108 the film 240 may be partially consumed, as depicted in FIG. 21.

At step 110B, the remaining silicon dioxide film 240 is removed from the substrate (FIG. 2J). In one illustrative embodiment, step 110B uses the process described above in reference to step 110A.

Step 110B post-etch residues 248 may be formed on the substrate (FIG. 2J). At step 112B such post-etch residue 248 may be removed by dipping the substrate 200 in an aqueous solution including hydrogen fluoride (HF) (as described above with respect to step 110A). In one illustrative embodiment, the aqueous solution comprises hydrogen fluoride and deionized water in a ratio of 1:100 (HF:H₂).

At step 114B, the wells 231 and 233 are formed using, e.g., processes discussed above in reference to steps 112A and 114A, respectively. At step 116, the embodiment 100B ends.

The embodiment 100C (FIG. 1C), similar to the embodiment 100A, starts at step 101 and sequentially performs steps 102 and 104.

At step 106C, a film 250 of α-carbon is deposited onto the wafer 200 (FIG. 2K). Step 106C uses a conventional plasma enhanced chemical vapor deposition (PECVD) process that produces the film 250 having poor step coverage, e.g., about 15% or less. As such, a thickness 252 of the α-carbon film 250 on the frontal surface 226 is about 4-6 times greater than a thickness 254 of the film on the sidewall 228 and in the corner 227. In one illustrative embodiment, the film 250 is deposited to the thickness 252 of about 50-100 Angstroms, however, in other embodiments, the film 250 may be formed to a different thickness. Suitable inorganic carbon deposition techniques are described, for example, in commonly assigned in U.S. patent application Ser. No. 09/590,322, filed Jun. 8, 2000 (Attorney docket number 4227), which is herein incorporated by reference.

At step 108C, the sidewalls 228 of the recesses 230 are etched using the lateral etch process (FIG. 2L). In one embodiment, steps 108C and 108A use the same etch chemistry. During a first phase, step 108C isotropically etches the film 250 and promptly exposes the sidewall 228 and corner region 227 by removing a thin film of α-carbon (i.e., film having the thickness 254) from the surface 228 and corner region 227. During a second phase, step 108C laterally etches the exposed sidewall 228 in the corner region 227 thus transforming the sidewall 228 into a surface 258 and defining the width 236 of the channel region 234 of the field effect transistor being fabricated. Similar to step 108A, step 108C continues until the channel region 234 is etched the pre-determined width 256. In one illustrative embodiment, step 108C uses the process described above in reference to step 108A. Such process provides selectivity to silicon over α-carbon of about 5:1, and at the end of step 108C the film 250 may be partially consumed, as depicted in FIG. 2K.

At step 110C, the remaining α-carbon film 250 is plasma etched and removed in the regions 222, as well as from the mask 210 (FIG. 2M). In one illustrative embodiment, step 110C uses a plasma comprising oxygen and an inert diluent gas such as argon, and the like. During step 110C, the mask 210 protects the film stack 201, while the silicon wafer 200 can be used as an etch stop layer. Alternatively, step 110C may also be used to remove the a-carbon mask 210 contemporaneously with the α-carbon film 212.

Step 110C can be performed in the DPS reactor. In one embodiment, step 110C provides oxygen at a rate between 10 and 200 sccm and argon at a rate between 10 to 200 sccm (i.e., an O₂:Ar flow ratio ranging from 1:20 to 20:1), applies between 500 and 1500 W of plasma power and between 0 and 500 W of bias power, and maintains a wafer temperature between 50 and 200 degrees Celsius at a pressure between 2 and 20 mTorr. One exemplary process provides O₂ at a rate of 30 sccm, Ar at a rate of 40 sccm (i.e., an O₂:Ar 0.75:1), 1000 W of plasma power, 100 W of bias power, a wafer temperature of 45 degrees Celsius, and a pressure of 4 mTorr. Alternatively, step 110C can be performed in the ASP reactor.

Step 110C may develop a post-etch residue 260 that should be removed prior to completion of the process 100C. At steps 112C, the residue 260 is removed and, at step 114C, the wells 231 and 233 are formed using, e.g., processes discussed above in reference to steps 112A and 114A, respectively. At step 116, the embodiment 100C ends.

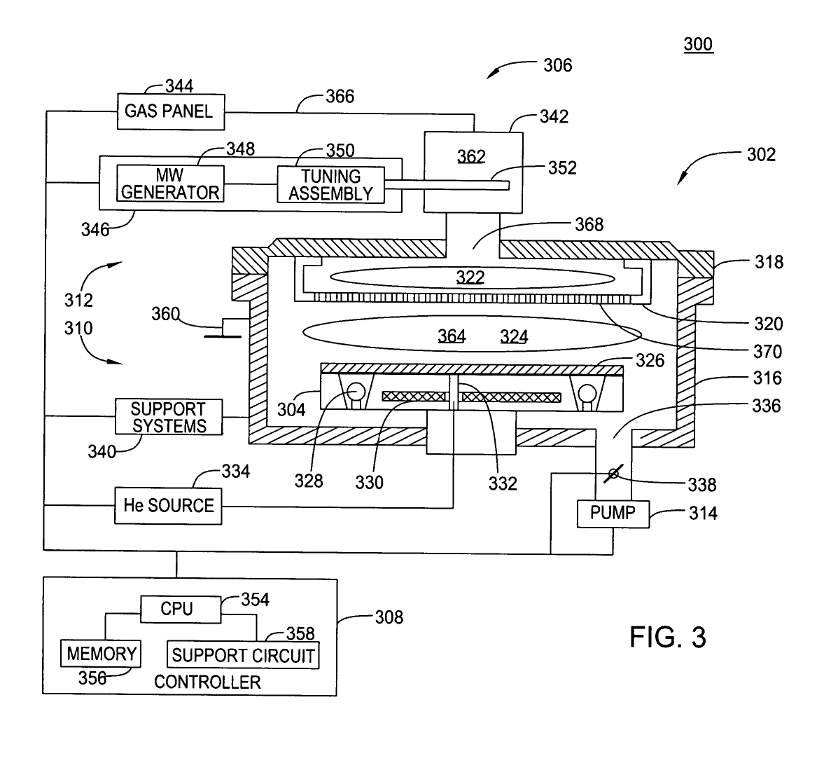

FIG. 3 depicts a schematic diagram of an ASP reactor 300 that may be used to practice portions of the embodiments 100A-100C. The reactor 300 comprises a process chamber 302, a remote plasma source 306, and a controller 308.

The process chamber 302 generally is a vacuum vessel, which comprises a first portion 310 and a second portion 312. In one embodiment, the first portion 310 comprises a substrate pedestal 304, a sidewall 316 and a vacuum pump 314. The second portion 312 comprises a lid 318 and a gas distribution plate (showerhead) 320, which defines a gas mixing volume 322 and a reaction volume 324. The lid 318 and sidewall 316 are generally formed from a metal (e.g., aluminum (Al), stainless steel, and the like) and electrically coupled to a ground reference 360.

The substrate pedestal 304 supports a substrate (wafer) 326 within the reaction volume 324. In one embodiment, the substrate pedestal 304 may comprise a source of radiant heat, such as gas-filled lamps 328, as well as an embedded resistive heater 330 and a conduit 332. The conduit 332 provides a gas (e.g., helium) from a source 334 to the backside of the wafer 326 through grooves (not shown) in the wafer support surface of the pedestal 304. The gas facilitates heat exchange between the support pedestal 304 and the wafer 326. The temperature of the wafer 326 may be controlled at about 250 degrees Celsius.

The vacuum pump 314 is adapted to an exhaust port 336 formed in the sidewall 316 of the process chamber 302. The vacuum pump 314 is used to maintain a desired gas pressure in the process chamber 102, as well as evacuate the post-processing gases and other volatile compounds from the chamber. In one embodiment, the vacuum pump 314 comprises a throttle valve 338 to control a gas pressure in the process chamber 302.

The process chamber 302 also comprises conventional systems for retaining and releasing the wafer 326, detecting an end of a process, internal diagnostics, and the like. Such systems are collectively depicted in FIG. 1 as support systems 340.

The remote plasma source comprises a microwave power source 346, a gas panel 344, and a remote plasma chamber 342. The microwave power source 346 comprises a microwave generator 348, a tuning assembly 350, and an applicator 352. The microwave generator 348 is generally capable of producing of about 200 W to 3000 W at a frequency of about 0.8 to 3.0 GHz. The applicator 352 is coupled to the remote plasma chamber 342 to energize a process gas (or gas mixture) 364 in the remote plasma chamber 342 to a microwave plasma 362.

The gas panel 344 uses a conduit 366 to deliver the process gas 364 to the remote plasma chamber 342. The gas panel 344 (or conduit 366) comprises means (not shown), such as mass flow controllers and shut-off valves, to control gas pressure and flow rate for each individual gas supplied to the chamber 342. In the microwave plasma 362, the process gas 364 is ionized and dissociated to form reactive species.

The reactive species are directed into the mixing volume 322 through an inlet port 368 in the lid 318. To minimize charge-up plasma damage to devices on the wafer 326, the ionic species of the process gas 364 are substantially neutralized within the mixing volume 322 before the gas reaches the reaction volume 324 through a plurality of openings 370 in the showerhead 320.

The controller 308 comprises a central processing unit (CPU) 354, a memory 356, and a support circuit 358. The CPU 354 may be of any form of a general-purpose computer processor used in an industrial setting. Software routines can be stored in the memory 356, such as random access memory, read only memory, floppy or hard disk, or other form of digital storage. The support circuit 358 is conventionally coupled to the CPU 354 and may comprise cache, clock circuits, input/output sub-systems, power supplies, and the like.

The software routines, when executed by the CPU 354, transform the CPU into a specific purpose computer (controller) 308 that controls the reactor 300 such that the processes are performed in accordance with the present invention. The software routines may also be stored and/or executed by a second controller (not shown) that is located remotely from the reactor 300.

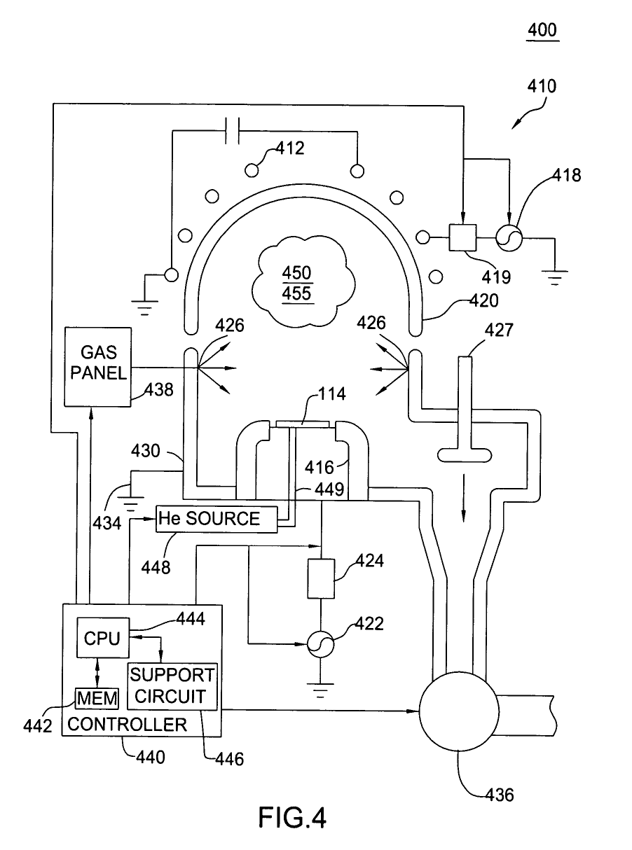

FIG. 4 depicts a schematic diagram of a DPS etch reactor 400 that may be used to practice portions of the embodiments 100A-100C. The reactor 400 comprises a process chamber 410 having a wafer support pedestal 416 within a conductive body (wall) 430, and a controller 440. Other suitable DPS reactors may include DPS I, DPS 11 and DPS+reactors.

The support pedestal (cathode) 416 is coupled, through a first matching network 424, to a biasing power source 422. The biasing source 422 generally is a source of up to 500 W at a frequency of approximately 13.56 MHz that is capable of producing either continuous or pulsed power. In other embodiments, the source 422 may be a DC or pulsed DC source. The chamber 410 is supplied with a dome-shaped dielectric ceiling 420. Other modifications of the chamber 410 may have other types of ceilings, e.g., a substantially flat ceiling. Above the ceiling 420 is disposed an inductive coil antenna 412. The antenna 412 is coupled, through a second matching network 419, to a plasma power source 418. The plasma source 418 typically is capable of producing up to 3000 W at a tunable frequency in a range from 50 kHz to 13.56 MHz. Typically, the wall 430 is coupled to an electrical ground 434.

A controller 440 comprises a central processing unit (CPU) 444, a memory 442, and support circuits 446 for the CPU 444 and facilitates control of the components of the chamber 410 and, as such, of the processes performed to accomplish the present invention, as discussed below in further detail.

In operation, a semiconductor wafer 414 is placed on the pedestal 416 and process gases are supplied from a gas panel 438 through entry ports 426 and form a gaseous mixture 450. The gaseous mixture 450 is ignited into a plasma 455 in the chamber 410 by applying power from the plasma and bias sources 418 and 422 to the antenna 412 and the cathode 416, respectively. The pressure within the interior of the chamber 410 is controlled using a throttle valve 427 and a vacuum pump 436. The temperature of the chamber wall 430 is controlled using liquid-containing conduits (not shown) that run through the wall 430.

The temperature of the wafer 414 is controlled by stabilizing a temperature of the support pedestal 416. In one embodiment, the helium gas from a gas source 448 is provided via a gas conduit 449 to channels formed by the back of the wafer 414 and grooves (not shown) in the pedestal surface. The helium gas is used to facilitate heat transfer between the pedestal 416 and the wafer 414. During the processing, the pedestal 416 may be heated by a resistive heater (not shown) within the pedestal to a steady state temperature and then the helium gas facilitates uniform heating of the wafer 414. Using such thermal control, the wafer 414 is maintained at a temperature of between 0 and 500 degrees Celsius.

Those skilled in the art will understand that other forms of chambers may be used to practice the invention, including chambers with remote plasma sources, microwave plasma chambers, electron cyclotron resonance (ECR) plasma chambers, and the like.

To facilitate control of the process chamber 410 as described above, the controller 440 may be one of any form of general-purpose computer processor that can be used in an industrial setting for controlling various chambers and sub-processors. The memory, or computer-readable medium, 442 of the CPU 444 may be one or more of readily available memory such as random access memory (RAM), read only memory (ROM), floppy disk, hard disk, or any other form of digital storage, local or remote. The support circuits 446 are coupled to the CPU 444 for supporting the processor in a conventional manner. These circuits include cache, power supplies, clock circuits, input/output circuitry and subsystems, and the like. The inventive method is generally stored in the memory 442 as a software routine. The software routine may also be stored and/or executed by a second CPU (not shown) that is remotely located from the hardware being controlled by the CPU 444.

The invention may be practiced in other semiconductor systems wherein the processing parameters may be adjusted to achieve acceptable characteristics by those skilled in the arts by utilizing the teachings disclosed herein without departing from the spirit of the invention.

Although the forgoing discussion referred to fabrication of the field effect transistor, fabrication of the other structures and features used in the integrated circuits and devices can benefit from the invention.

While foregoing is directed to the illustrative embodiment of the present invention, other and further embodiments of the invention may be devised without departing from the basic scope thereof, and the scope thereof is determined by the claims that follow.

What is claimed is:

1. A method of fabricating an ultra shallow junction of a field effect transistor, comprising:
(a) supplying a substrate comprising a gate structure of the transistor;
(b) etching a surface of the substrate in source and drain regions of the transistor;
(c) selectively forming a protective film on said surface of the substrate;
(d) laterally etching the substrate beneath a gate dielectric of the gate structure; and
(e) removing the protective film.

2. The method of claim 1 wherein the substrate is a silicon wafer.

3. The method of claim 1 wherein the gate structure comprises the gate dielectric and a gate electrode formed on the gate dielectric.

4. The method of claim 1 wherein the step (b) further comprises:
providing Cl₂ and HBr at a flow ratio Cl₂:HBr in a range from about 1:15 to 15:1.

5. The method of claim 1 wherein the step (d) further comprises:
providing HBr and Cl₂ at a flow ratio HBr:Cl₂ in a range from about 1:15 to 15:1.

6. The method of claim 1 wherein the step (c) further comprises:
oxidizing portions of said regions of the transistor.

7. The method of claim 6 further comprising:
providing a directional oxygen plasma using a cathode bias of 20 to 200 W.

8. The method of claim 6 wherein the step (e) further comprises:
providing carbon tetrafluoride (CF₄) at a flow rate of 50 sccm, applying 500 W of power to the inductively coupled antenna, applying 40 W of bias power to the cathode and maintaining a wafer temperature of 50 degrees at a chamber pressure of 4 mtorr.

9. The method of claim 1 wherein the step (c) further comprises:
depositing a silicon dioxide layer on portions of said regions of the transistor.

10. The method of claim 9 wherein the step (e) further comprises:
providing carbon tetrafluoride (CF₄) at a flow rate of 50 sccm, applying 500 W of power to the inductively coupled antenna, applying 40 W of bias power to the cathode and maintaining a wafer temperature of 50 degrees at a chamber pressure of 4 mtorr.

11. The method of claim 1 wherein the step (c) further comprises:
depositing a carbon layer on portions of said regions of the transistor.

12. The method of claim 11 wherein the step (e) further comprises:
providing O₂ and Ar at a flow ratio O₂:Ar in a range from about 1:20 to 20:1.

13. The method of claim 1 wherein the step (e) further comprises removal of residue.

14. The method of claim 13 further comprising:
providing CF₄ and H₂O at a flow ratio CF₄:H₂O in a range from about 1:10 to 10:1.

15. The method of claim 1 further comprising:
depositing doped epitaxial films to form a source and a drain of the transistor.

16. A method of fabricating an ultra shallow junction of a field effect transistor, comprising:
supplying a silicon substrate comprising a gate structure of the transistor;
etching a surface of the substrate in source and drain regions of the transistor by providing Cl₂ and HBr at a flow ratio Cl₂:HBr of 10:1, applying 350 W to an inductively coupled antenna and 40 W of substrate bias power, and maintaining the substrate at 45 degrees Celsius at a chamber pressure of 25 mTorr;
forming a protective film on portions of said etched surface using a directional oxygen plasma, a cathode bias of 20 to 200 W and maintaining the substrate at 50 degrees Celsius at a chamber pressure of 10 mTorr;
laterally etching the substrate beneath a gate dielectric of the gate structure by providing HBr and Cl₂ at a flow ratio HBr:Cl₂ of about 3:1 and 30% by volume of oxygen (O₂) in helium (He) at a rate of 6 sccm, applying 700 W to an inductively coupled antenna and 65 W of substrate bias power, and maintaining the substrate at 50 degrees Celsius at a chamber pressure of 70 mTorr;
removing the protective film by providing carbon tetrafluoride (CF₄) at a flow rate of 50 sccm, applying 500 W of power to the inductively coupled antenna, applying 40 W of bias power to the cathode and maintaining a wafer temperature of 50 degrees at a chamber pressure of 4 mtorr;
removing residue by dipping the substrate in an aqueous solution including hydrogen fluoride, and
depositing doped epitaxial films into the etched portions of the substrate to form a source and a drain of the transistor.

17. A method of fabricating an ultra shallow junction of a field effect transistor, comprising:
supplying a silicon substrate comprising a gate structure of the transistor;
etching a surface of the substrate in source and drain regions of the transistor by providing Cl₂ and HBr at a flow ratio Cl₂:HBr of 10:1, applying 350 W to an inductively coupled antenna and 40 W of substrate bias power, and maintaining the substrate at 45 degrees Celsius at a chamber pressure of 25 mTorr;
depositing a silicon oxide protective film on portions of said etched surface;
laterally etching the substrate beneath a gate dielectric of the gate structure by providing HBr and Cl₂ at a flow ratio HBr:Cl₂ of about 3:1 and 30% by volume of oxygen (O₂) in helium (He) at a rate of 6 sccm, applying 700 W to an inductively coupled antenna and 65 W of substrate bias power, and maintaining the substrate at 50 degrees Celsius at a chamber pressure of 70 mTorr;
removing the silicon oxide protective film by providing carbon tetrafluoride (CF₄) at a flow rate of 50 sccm, applying 500 W of power to the inductively coupled antenna, applying 40 W of bias power to the cathode and maintaining a wafer temperature of 50 degrees at a chamber pressure of 4 mtorr;
removing residue by dipping the substrate in an aqueous solution including hydrogen fluoride, and
depositing doped epitaxial films into the etched portions of the substrate to form a source and a drain of the transistor.

18. A method of fabricating an ultra shallow junction of a field effect transistor, comprising:
supplying a silicon substrate comprising a gate structure of the transistor;
etching a surface of the substrate in source and drain regions of the transistor by providing Cl₂ and HBr at a flow ratio Cl₂:HBr of 10:1, applying 350 W to an inductively coupled antenna and 40 W of substrate bias power, and maintaining the substrate at 45 degrees Celsius at a chamber pressure of 25 mTorr;
depositing an amorphous carbon protective film on portions of said etched surface;
laterally etching the substrate beneath a gate dielectric of the gate structure by providing HBr and Cl₂ at a flow ratio HBr:Cl₂ of about 3:1 and 30% by volume of oxygen (O₂) in helium (He) at a rate of 6 sccm, applying 700 W to an inductively coupled antenna and 65 W of substrate bias power, and maintaining the substrate at 50 degrees Celsius at a chamber pressure of 70 mTorr;
removing the amorphous carbon protective film providing O₂ and Ar at a flow ratio O₂:Ar of about 0.75:1, applying 1000 W to an inductively coupled antenna and 100 W of substrate bias power, and maintaining the substrate at 45 degrees Celsius at a chamber pressure of 4 mTorr;
removing residue by dipping the substrate in an aqueous solution including hydrogen fluoride; and
depositing doped epitaxial films into the etched portions of the substrate to form a source and a drain of the transistor.

19. A computer-readable medium including software that, when executed by a processor, performs a method that causes a semiconductor substrate processing platform to fabricate an ultra shallow junction of a field effect transistor, comprising:
(a) supplying a substrate comprising a gate structure of the transistor;
(b) etching a surface of the substrate in source and drain regions of the transistor;
(c) selectively forming a protective film on said surface of the substrate;
(d) laterally etching the substrate beneath a gate dielectric of the gate structure; and
(e) removing the protective film.

20. The computer-readable medium of claim 19 wherein the step (b) further comprises:
providing Cl₂ and HBr at a flow ratio Cl₂:HBr in a range from about 1:15 to 15:1.

21. The computer-readable medium of claim 19 wherein the step (d) further comprises:
providing HBr and Cl₂ at a flow ratio HBr:Cl₂ in a range from about 1:15 to 15:1.

22. The computer-readable medium of claim 19 wherein the step (c) further comprises:
oxidizing portions of said regions of the transistor.

23. The computer-readable medium of claim 22 wherein the step (e) further comprises:
providing carbon tetrafluoride (CF₄) at a flow rate of 50 sccm, applying 500 W of power to the inductively coupled antenna, applying 40 W of bias power to the cathode and maintaining a wafer temperature of 50 degrees at a chamber pressure of 4 mtorr.

24. The computer-readable medium of claim 19 wherein the step (c) further comprises:
depositing a silicon oxide layer on portions of said regions of said transistor.

25. The computer-readable medium of claim 24 wherein the step (e) further comprises:
providing carbon tetrafluoride (CF₄) at a flow rate of 50 sccm, applying 500 W of power to the inductively coupled antenna, applying 40 W of bias power to the cathode and maintaining a wafer temperature of 50 degrees at a chamber pressure of 4 mtorr.

26. The computer-readable medium of claim 19 wherein the step (c) further comprises:
depositing an inorganic carbon layer on portions of said regions of the transistor.

27. The computer-readable medium of claim 26 wherein the step (e) further comprises:
providing O₂ and Ar at a flow ratio O₂:Ar in a range from about 1:20 to 20:1.

28. The computer-readable medium of claim 19 wherein the step (e) further comprises removal of residue.

29. The computer-readable medium of claim 28 further comprising:
dipping the substrate in an aqueous solution including hydrogen fluoride.

30. The computer-readable medium of claim 19 further comprising:
depositing doped epitaxial films to form a source and a drain of the transistor.
